(19) United States
(12) Patent Application Publication
(10) Pub. No.: US 2016/0104805 A1
(43) Pub. Date: Apr. 14, 2016

(54) OPTICAL SEMICONDUCTOR DEVICE INCLUDING BLACKENED TARNISHABLE BOND WIRES AND RELATED METHODS

(71) Applicant: STMICROELECTRONICS PTE LTD, Singapore (SG)

(72) Inventors: Loic Pierre Louis Renard, Singapore (SG); Kok-Leong Cheng, Singapore (SG)

(21) Appl. No.: 14/512,619

(22) Filed: Oct. 13, 2014

(51) Int. Cl. H01L 31/02; H01L 27/14; H01L 31/18

(52) U.S. Cl. CPC H01L 31/02002; H01L 31/186; H01L 27/14

(57) ABSTRACT

A method for making an optical semiconductor device may include forming an integrated circuit (IC) including an optical sensing area and a bond pads outside the optical sensing area, and coupling proximal ends of respective bond wires to corresponding bond pads. The method may further include performing a blackening treatment on the bond wires.

### TECHNICAL FIELD

The present invention relates to the field of electronic devices and, more particularly, to optical semiconductor devices and related methods.

### BACKGROUND

Optical semiconductor devices are used for a wide variety of applications such as image sensors, camera modules and image signal processor (ISPs). As technology progresses, such optical semiconductor devices are called upon to produce ever higher resolution in increasingly more compact form factors for applications including digital still cameras, machine vision, automotive and gaming, for example.

However, with decreasing package size comes not only the typical packaging and performance challenges for semiconductor devices in general, but also additional considerations associated with accurate light detection in such small form factors. As such, it may be desirable to provide enhanced fabrication or processing techniques for creating next generation optical semiconductor devices.

### SUMMARY

A method for making an optical semiconductor device may include forming an integrated circuit (IC) comprising an optical sensing area and a plurality of bond pads outside the optical sensing area, and coupling proximal ends of a plurality of respective bond wires to corresponding bond pads. The method may further include performing a blackening treatment on the plurality of bond wires.

More particularly, distal ends of the plurality of bond wires may be coupled to corresponding contact areas on adjacent circuit board portions. The IC may be formed by forming the optical sensing area and plurality of bond pads on a semiconductor substrate without a guardband therebetween.

By way of example, the plurality of bond wires may comprise at least one tarnishable metal. In one embodiment, performing the blackening treatment may include exposing the at least one tarnishable metal to an oxygen-containing plasma. In accordance with another example embodiment, the blackening treatment may include exposing the at least one tarnishable metal to a wet cleaning solution. In still another example embodiment, the blackening treatment may include exposing the at least one tarnishable metal to a sulfur treatment. In yet another example embodiment, performing the blackening treatment may include exposing the at least one tarnishable metal to a gas comprising at least one of oxygen and sulfur. By way of example, the plurality of bond wires may comprise silver, copper, etc.

A related optical semiconductor device may include an integrated circuit (IC) including an optical sensing area and a plurality of bond pads outside the optical sensing area, and a plurality of respective bond wires having proximal ends coupled to corresponding bond pads. More particularly, the plurality of bond wires may comprise a blackened tarnishable metal.

### BRIEF DESCRIPTION OF THE DRAWINGS

FIG. 1 is a top view of an optical semiconductor device including a plurality of blackened tarnishable bond wires in accordance with an example embodiment.

FIG. 2 is a flow diagram illustrating example method aspects for making the semiconductor device of FIG. 1.

FIG. 3 is a top view of an optical semiconductor device in accordance with a conventional approach.

### DETAILED DESCRIPTION

The present invention will now be described more fully hereinafter with reference to the accompanying drawings, in which preferred embodiments of the invention are shown, This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

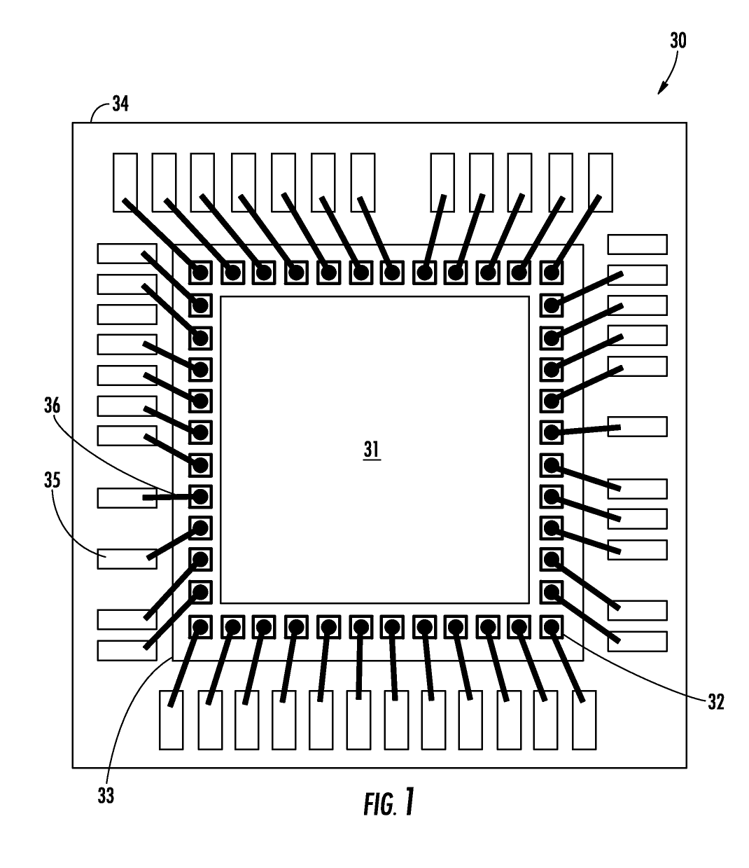

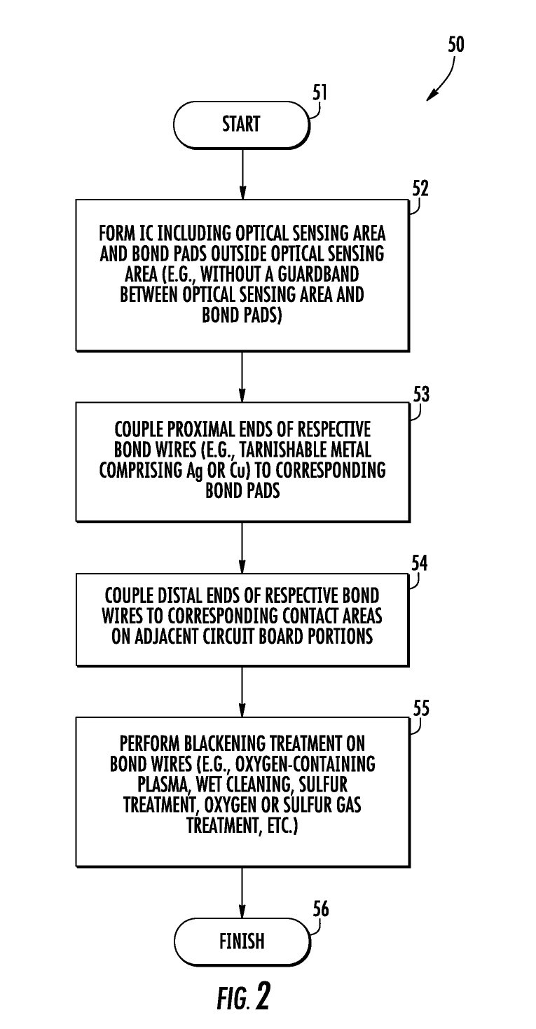

Referring initially to FIGS. 1-2 and the flow diagram 50, a method for making an optical semiconductor device 30 is first described. Beginning at Block 51, the method illustratively includes forming an integrated circuit (IC) comprising an optical sensing area 31 and a plurality of bond pads 32 outside the optical sensing area. By way of example, the optical sensing area may include a plurality of complementary metal oxide semiconductor (CMOS) circuit elements, as will be appreciated by those skilled in the art. The optical sensing elements in the area 31 and bond pads 32 may be formed on a semiconductor substrate 33 (e.g., silicon, etc.), which is coupled to a respective circuit board 34 having a plurality of contact areas 35 to be coupled with respective bond pads 32 of the IC. The contact areas 35 may, in turn, be connected through conductive vies or circuit traces to package connectors such as ball grid array connectors, etc. (not shown) so that the packaged IC may be electrically coupled with other components in electronic devices such as mobile phones, cameras, etc., as will be appreciated by those skilled in the art. An example package type is a Small Optical Package (SmOP), such as made by the assignee of the present application, and as will also be appreciated by those skilled in the art.

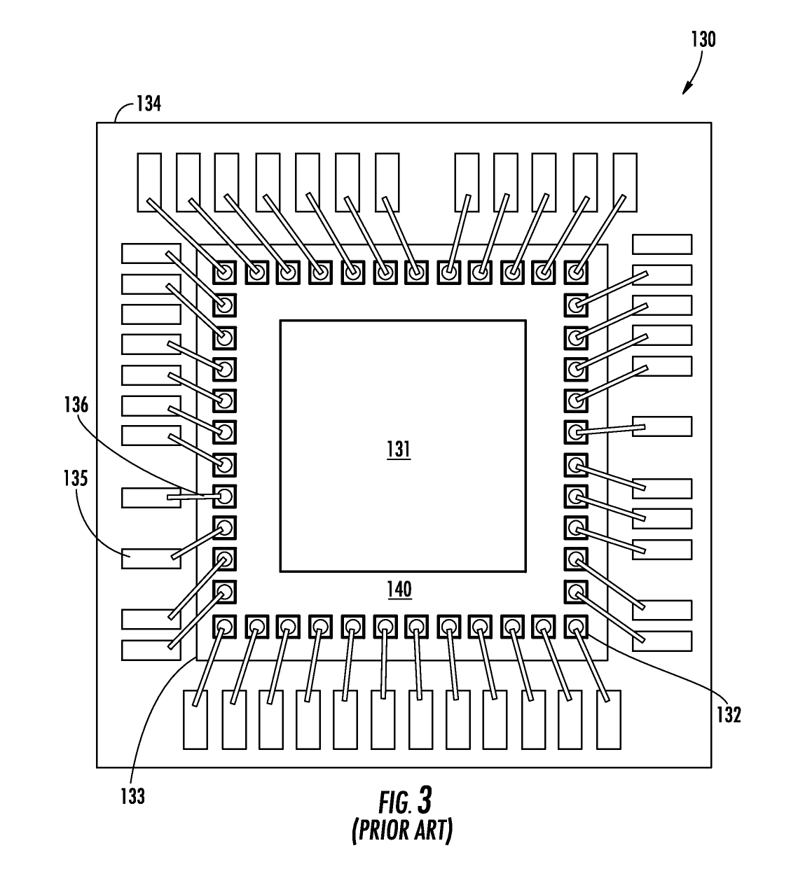

The bond pads 32 are typically coupled to the contact areas 35 with conductive bond wires 36. More particularly, a proximal end of each bond wire 36 is coupled to a respective bond pad 32, and the distal end of the bond wire is coupled to a corresponding contact area 35, as will be appreciated by those skilled in the art, at Blocks 53-54. In accordance with a conventional approach now described with reference to the optical semiconductor device 130 of FIG. 3, the material typically used for bond wires 136 is gold (Au). The optical semiconductor device 130 also includes an optical sensing area 131, bond pads 132, substrate 133, circuit board 134, and contact areas 135 similar to those described above with respect to FIG. 1.

While gold provides desired conductivity and mechanical properties for bond wire interconnects, a potential drawback of this material for relatively compact optical sensing devices is that it has a relatively high reflectivity, meaning that it can cause undesired or stray light to be reflected onto the optical sensing area 131. As a result, a guardband 140 is typically reserved around the active optical sensing area 131 to mitigate the effects of such stray light reflected from the gold bond wires 136. Yet, as recognized by the present inventors, this is disadvantageous in that it occupies valuable real estate that could otherwise be used to increase the size and/or density of the active optical sensing area 131. Moreover, despite the existence of the guardband 140, some stray light may still be reflected from the gold bond wires 136 to the active sensor area 131.

In accordance with the example embodiment of FIG. 1, a tarnishable metal or metal alloy is used for the bond wires 36. By way of example, such tarnishable metals may include silver (Ag) or copper (Cu), either individually or as part of an alloy. Moreover, a blackening treatment is also performed on the bond wires 36 to diminish or reduce the reflectivity of the bond wires, at Block 55, which illustratively concludes the method of FIG. 2 (Block 56). As a result of the diminished reflectivity of the bond wires 36, the optical semiconductor device 30 may advantageously be formed with a relatively smaller guardband, or no guardband at all between the active optical sensing area 31 and the bond pads 32, as is the case in the example of FIG. 1.

By way of example, the blackening treatment may include an oxygen-containing plasma treatment. Other potential blackening treatments may include a wet cleaning, sulfur treatment, as well as exposure to a gas including oxygen and/or sulfur, for example. However, it will be appreciated that different types of treatments may be appropriate for different tarnishable metals, and one may also consider whether the adjacent circuit components are compatible with a given blackening treatment, for example.

By way of example, the optical semiconductor device may be used for various types of devices such as the following: CMOS image sensors; CMOS photonic sensors; imaging modules; imaging processors; Pico projection video processors; proximity sensors; and ambient light sensors. However, the techniques described herein may be applicable to other types of optical semiconductor devices as well, as will be understood by those skilled in the art.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A method for making an optical semiconductor device comprising:
forming an integrated circuit (IC) comprising an optical sensing area and a plurality of bond pads outside the optical sensing area;
coupling proximal ends of a plurality of respective bond wires to corresponding bond pads; and
performing a blackening treatment on the plurality of bond wires.

2. The method of claim 1 further comprising coupling distal ends of the plurality of bond wires to corresponding contact areas on adjacent circuit board portions.

3. The method of claim 1 wherein forming the IC comprises forming the optical sensing area and plurality of bond pads on a semiconductor substrate without a guardband therebetween.

4. The method of claim 1 wherein the plurality of bond wires comprises at least one tarnishable metal.

5. The method of claim 4 wherein performing the blackening treatment comprises exposing the at least one tarnishable metal to an oxygen-containing plasma.

6. The method of claim 4 wherein performing the blackening treatment comprises exposing the at least one tarnishable metal to a wet cleaning solution.

7. The method of claim 4 wherein performing the blackening treatment comprises exposing the at least one tarnishable metal to a sulfur treatment.

8. The method of claim 4 wherein performing the blackening treatment comprises exposing the at least one tarnishable metal to a gas comprising at least one of oxygen and sulfur.

9. The method of claim 1 wherein the plurality of bond wires comprise silver.

10. The method of claim 1 wherein the plurality of bond wires comprise copper.

11. A method for making an optical semiconductor device comprising:
forming an integrated circuit (IC) comprising an optical sensing area and a plurality of bond pads outside the optical sensing area on a semiconductor substrate without a guardband between the optical sensing area and the plurality of bond pads;
coupling proximal ends of a plurality of respective bond wires to corresponding bond pads, the plurality of bond wires comprising silver; and
performing a blackening treatment on the plurality of bond wires.

12. The method of claim 11 further comprising coupling distal ends of the plurality of bond wires to corresponding contact areas on adjacent circuit board portions.

13. The method of claim 10 wherein performing the blackening treatment comprises exposing the plurality of bond wires to an oxygen-containing plasma.

14. The method of claim 10 wherein performing the blackening treatment comprises exposing the plurality of bond wires to a wet cleaning solution.

15. The method of claim 10 wherein performing the blackening treatment comprises exposing the plurality of bond wires to a sulfur treatment.

16-20. (canceled)

21. A method for making an optical semiconductor device comprising:
forming an integrated circuit (IC) comprising an optical sensing area and a plurality of bond pads outside the optical sensing area;
coupling proximal ends of a plurality of respective bond wires to corresponding bond pads, the bond wires comprising at least one tarnishable metal; and
performing a blackening treatment on the plurality of bond wires to form a layer of tarnish thereon.

22. The method of claim 21 wherein performing the blackening treatment comprises exposing the at least one tarnishable metal to an oxygen-containing plasma.

23. The method of claim 21 wherein performing the blackening treatment comprises exposing the at least one tarnishable metal to a wet cleaning solution.

24. The method of claim 21 wherein performing the blackening treatment comprises exposing the at least one tarnishable metal to a sulfur treatment.

25. The method of claim 21 wherein performing the blackening treatment comprises exposing the at least one tarnishable metal to a gas comprising at least one of oxygen and sulfur.
